(19) United States
(12) Patent Application Publication
(10) Pub. No.: US 2026/0122929 A1
(43) Pub. Date: Apr. 30, 2026

(54) ULTRATHIN NANOPOROUS POLYMER DIELECTRIC LAYER ON 2D MATERIAL, AND THIN FILM DEVICE COMPRISING THE SAME

(71) Applicant: VILLANOVA UNIVERSITY, VILLANOVA, PA (US)

(72) Inventors: BO LI, MALVERN, PA (US); MINGYUAN SUN, BRYN MAWR, PA (US); DONG ZHOU, GUANGZHOU CITY (CN)

(73) Assignee: VILLANOVA UNIVERSITY, VILLANOVA, PA (US)

(21) Appl. No.: 19/367,177

(22) Filed: Oct. 23, 2025

Related U.S. Application Data
(60) Provisional application No. 63/711,280, filed on Oct. 24, 2024.

(51) Int. Cl. H10D 1/68

(52) U.S. Cl. CPC H10D 1/68

(57) ABSTRACT

A capacitor at nanometer level and a resulting nanodevice such as a sensor are provided. The nanodevice includes a substrate, and a first 2D material layer disposed over the substrate and comprising a 2D material and being electrically conductive. The nanodevice further includes a polymeric nanoporous dielectric layer (NDL) disposed on the first 2D material layer. The polymeric NDL comprises a polymer having a crystalline structure and having lamellae substantially normal to a plane of the first 2D material. A conductive material layer is disposed on the polymeric NDL. The conductive material layer comprises a second 2D material layer or comprises a different electrically conductive material. The first 2D material, the polymeric NDL, and the conductive material layer are configured to provide a capacitor structure at a nanometer level. A method of making the capacitor or the nanodevice, and a method of using the same are also provided.

### PRIORITY CLAIM AND CROSS-REFERENCE

This application claims the benefit of U.S. Provisional Application No. 63/711,280, filed Oct. 24, 2024, which application is expressly incorporated by reference herein in its entirety.

### FIELD OF THE INVENTION

The disclosure relates to thin films and thin film based electronics generally. More particularly, the disclosed subject matter relates to an ultrathin polymer layer, a thin film electronic device comprising the same, methods of making the same, and methods of using the same.

### BACKGROUND

Next-generation soft electronics especially sensor and actuation systems require an ultrathin but deformable dielectric layer. Continuous polymer dielectric film with “soft” nature such as polyimide, polynorbornenes, polytetrafluoroethylene (PTFE), and poly(1,3,5-trimethyl-1,3,5-trivinyl cyclotrisiloxane) (pV3D3) are emerging as promising candidates. Such a layer can be achieved through a spin coating or chemical vapor deposition (CVD), and the thickness of polymer film can be controlled as low as 11 nm using CVD method. Such polymer dielectric film enables excellent device bendability. However, the solid nature of such films limits the deformation in the z direction perpendicular to the film (i.e., x-y plane), thus restricts their application in sensing and actuating.

Inorganic dielectric materials based on oxides and nitrides provide high dielectric constant, low leakage, and mechanical and electrical stability at high temperatures. However, their high mechanical stiffness and brittleness limits the applications in soft and flexible electronics especially in the applications of sensors and actuators.

### SUMMARY OF THE INVENTION

The present disclosure provides a capacitor at nanometer level, a nanodevice or device such as a sensor comprising the capacitor, methods of making the same, and methods of using the same.

In accordance with some embodiments, the nanodevice comprises a substrate, and a first 2D material layer disposed over the substrate, and comprising a 2D material and being electrically conductive. The nanodevice further comprises a polymeric nanoporous dielectric layer (NDL) disposed on the first 2D material layer. The polymeric NDL comprises a polymer having a crystalline structure and having lamellae substantially normal to a plane of the first 2D material. A conductive material layer is disposed on the polymeric NDL. The conductive material layer comprises a second 2D material layer or comprises a different electrically conductive material. The first 2D material, the polymeric NDL, and the conductive material layer are configured to provide a capacitor structure at a nanometer level.

In some embodiments, the polymeric NDL has pores aligned with the lamellae and normal to the first 2D material layer. The porosity may be in a range of from about 60% to about 95% by volume, for example, in a range of from about 80% to 90% by volume.

The polymeric NDL may have a thickness in a range of from about 1 nm to about 5,000 nm. For example, in some embodiments, the polymeric NDL may have a thickness in a range of from about 5 nm to about 1,000 nm, for example, in a range of from about 5 nm to about 500 nm, in a range of from about 5 nm to about 400 nm, in a range of from about 5 nm to about 300 nm, in a range of from about 5 nm to about 200 nm, in a range of from about 5 nm to about 100 nm, in a range of from about 5 nm to about 50 nm, or any other suitable thickness range.

Each of the first 2D material layer and the conductive material layer may have a thickness in a range of from about 1 nm to about 5 nm. In some embodiments, each of the first 2D material layer and the conductive material layer is a monolayer.

In some embodiments, the device is transparent, for example, having a transparency in a range of from about 50% to about 98%. The device has a transparency in a range of from about 80% to about 95% in some embodiments.

The polymeric NDL is made by using the first 2D material layer as a template in an atomic template assembly (ATA) process.

The polymer in the polymeric NDL is a suitable polymer having a crystalline structure. Examples of a suitable polymer include, but are not limited to, polyethylene, polypropylene, any other polyolefins, polyester, polyamide, acetal (polyoxymethylene), and any combination thereof. For example, in some embodiments, the polymer in the polymeric NDL is polyethylene including, but not limited to high density polyethylene (HDPE) and low density polyethylene (LDPE).

The 2D material in the first or the second 2D material layer can be any suitable 2D material that is electrically conductive. Examples of a suitable 2D material include, but are not limited to graphene, graphene oxide, borophene, transition metal dichalcogenide, germanene, boron nitride nanosheet, titanate nanosheet, borocarbonitride, MXene (e.g., Ti₃C₂Tₓ), and any combination thereof. For example, in some embodiments, the 2D material comprises graphene. In some other embodiments, the 2D material comprises a transition metal dichalcogenide such as MoSe₂, WSe₂, MoS₂, and WS₂.

In the nanodevice, the polymeric NDL may have a dielectric constant in a range of form about 1.1 to about 1.2.

In accordance with some embodiments, the nanodevice is a sensor. Examples of a suitable sensor include, but are not limited to, a pressure sensor, a weight sensor, a mass sensor, a temperature sensor, a gas sensor, and any combination thereof.

The nanodevice may further comprise two conductive pads disposed on the substrate and electrically connected with the first 2D material layer and the conductive material layer. In some embodiments, the conductive material layer comprises a portion disposed on the substrate.

In another aspect, the present disclosure provides a method of making the nanodevice (or the capacitor or the sensor). Such a method comprises a step of growing the polymeric NDL on the first 2D material layer as a template.

In another aspect, the present disclosure provides a method of using the nanodevice (or the capacitor or the sensor). Such a method comprises a step of measuring a capacitance or a change in the capacitance of the capacitor.

### BRIEF DESCRIPTION OF THE DRAWINGS

The present disclosure is best understood from the following detailed description when read in conjunction with the accompanying drawings. It is emphasized that, according to common practice, the various features of the drawings are not necessarily to scale. On the contrary, the dimensions of the various features are arbitrarily expanded or reduced for clarity. Like reference numerals denote like features throughout specification and drawings.

FIGS. 1A-1D are schematic drawings illustrating the solution growth process of the polymeric nanoporous dielectric layer (NDL) on 2D materials in accordance with some embodiments.

FIG. 2 shows a top-view SEM image of PE-MoSe₂ hybrid nanostructure.

FIG. 3 shows a side-view SEM image of PE-graphene hybrid nanostructure.

FIG. 4 is a SEM image showing PE-MoSe₂ on SiO₂ particles, while the insert is a cross-sectional schematic illustration.

FIG. 5 shows an inch-scale PE-graphene film on glass slide showing the transparency.

FIG. 6A shows the relationship between the height of the PE lamellae and the assembly time under different temperatures and on different substrates.

FIG. 6B shows the relationship between the height of the PE lamellae and the assembly time under 100° C. and on MoSe₂ substrate.

FIGS. 7A-7B show a top-view AFM image and a line profile of PE-MoSe₂ hybrid nanostructure.

FIGS. 7C-7D show a top-view AFM image and a line profile of PE-Graphene hybrid nanostructure.

FIGS. 8A-8F are sectional views illustrating an exemplary manufacturing process of an exemplary capacitor, for example, a Graphene-Polyethylene (NDL)-Graphene (GPG) capacitor, in accordance with some embodiments.

FIG. 9A is a sectional view schematically illustrating an exemplary GPG capacitor in accordance with some embodiments.

FIGS. 9B-9C and FIGS. 9D-9E show a top-view AFM image and a line profile of Graphene-PE and Graphene-PE-Graphene, respectively.

FIG. 10 shows the dielectric constant data of the capacitors of 6.1 nm PE NDL, 40.3 nm PE NDL, 6.1 nm HDPE lamellae, 40.3 nm HDPE lamellae, and 40 nm SiO₂ DL.

FIG. 11 a sectional view illustrating an exemplary pressure sensor made in the present disclosure.

FIG. 12A shows the relationship between the capacitance and the time of a bug weight sensing test on a 42.1 nm capacitor.

FIG. 12B shows the relationship between the capacitance and the mass of a bug weight sensing test on the 42.1 nm capacitor.

FIG. 12C shows the relationship between the capacitance and the pressure of the bug weight sensing test on the 42.1 nm capacitor.

FIG. 13A shows the relationship between the capacitance and the time of a bug weight sensing test on a 7.8 nm capacitor.

FIG. 13B shows the relationship between the capacitance and the mass of bug weight sensing test on the 7.8 nm capacitor.

FIG. 13C shows the relationship between the capacitance and the pressure of bug weight sensing test on the 7.8 nm capacitor.

FIG. 14 shows the capacitance and the time of the bug weight sensing test on capacitors with 40 nm PE NDL and 40 nm SiO₂ DL.

FIG. 15A is a schematic drawing illustrating an exemplary GPG capacitor having three-by-three arrays in accordance with some embodiments.

FIG. 15B is an exploded view illustrating the exemplary GPG capacitor of FIG. 15A.

FIG. 15C is an image showing the GPG capacitor having the three-by-three arrays.

FIG. 15D is a schematic diagram illustrating a “Z” letter test.

FIG. 15E is a perspective view illustrating the exemplary GPG capacitor under the “Z” letter test.

FIG. 15F illustrates five-by-five arrays in an exemplary GPG capacitor.

FIG. 15G shows a color map of the five-by-five arrays in the GPG capacitor under sensing test.

FIG. 15H illustrates ten-by-ten arrays in an exemplary GPG capacitor.

FIG. 15I shows the success rate of the ten-by-ten arrays in the GPG capacitor under sensing test.

FIG. 15J shows normal distribution of the dielectric constant values in the ten-by-ten arrays in the GPG capacitor.

FIG. 16A is an image demonstrating a GPG capacitor on a PEI substrate.

FIG. 16B is an image demonstrating a side view of the GPG capacitor on the PEI substrate (held on a hand).

FIG. 17A shows the relationship between the capacitance and the time of bug weight sensing test on the capacitor with the PEI substrate.

FIG. 17B shows the relationship between the capacitance and the mass of bug weight sensing test on the capacitor with PEI substrate.

FIG. 17C shows the relationship between the capacitance and the pressure of bug weight sensing test on the capacitor with the PEI substrate.

FIG. 17D compares the data of capacitance versus time of the GPG capacitors on different substrates, including Si/SiO₂ and PEI, respectively.

FIG. 17E compares the data of capacitance versus pressure of the GPG capacitors on different substrates, including Si/SiO₂ and PEI, respectively.

FIG. 18A shows the relationship between the capacitance and the time of a temperature sensing test.

FIG. 18B shows the relationship between the capacitance and the temperature of the temperature sensing test.

FIG. 19A shows the relationship between the capacitance and the time of IPA a liquid drop evaporation test.

FIG. 19B shows the relationship between the capacitance and the weight in the IPA liquid drop evaporation test.

FIG. 20A shows the relationship between the capacitance and the time of the acetone liquid drop evaporation test.

FIG. 20B shows the relationship between the capacitance and the weight of the acetone liquid drop evaporation test.

FIG. 21 shows comparison of the exemplary capacitors with comparative organic-inorganic hybrid structure-based capacitors.

FIG. 22 shows x-ray diffraction (XRD) of PE-MoSe₂ hybrid nanostructure.

### DETAILED DESCRIPTION

This description of the exemplary embodiments is intended to be read in connection with the accompanying drawings, which are to be considered part of the entire written description. In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

For purposes of the description hereinafter, it is to be understood that the embodiments described below may assume alternative variations and embodiments. It is also to be understood that the specific articles, compositions, and/or processes described herein are exemplary and should not be considered as limiting.

In the present disclosure the singular forms “a,” “an,” and “the” include the plural reference, and reference to a particular numerical value includes at least that particular value, unless the context clearly indicates otherwise. When values are expressed as approximations, by use of the antecedent “about,” it will be understood that the particular value forms another embodiment. As used herein, “about X” (where X is a numerical value) preferably refers to ±10% of the recited value, inclusive. For example, the phrase “about 8” preferably refers to a value of 7.2 to 8.8, inclusive. Where present, all ranges are inclusive and combinable. For example, when a range of “1 to 5” is recited, the recited range should be construed as including ranges “1 to 4”, “1 to 3”, “1-2”, “1-2 & 4-5”, “1-3 & 5”, “2-5”, and the like. In addition, when a list of alternatives is positively provided, such listing can be interpreted to mean that any of the alternatives may be excluded, e.g., by a negative limitation in the claims. For example, when a range of “1 to 5” is recited, the recited range may be construed as including situations whereby any of 1, 2, 3, 4, or 5 are negatively excluded; thus, a recitation of “1 to 5” may be construed as “1 and 3-5, but not 2”, or simply “wherein 2 is not included.” It is intended that any component, element, attribute, or step that is positively recited herein may be explicitly excluded in the claims, whether such components, elements, attributes, or steps are listed as alternatives or whether they are recited in isolation.

For brevity, unless expressly indicated otherwise, references to “a 2D material” or “a single-layer material” made below will be understood to encompass a solid material consisting of a single layer of atoms. The 2D materials can generally be categorized as either 2D allotropes of various elements or as compounds, which comprises two or more covalently bonding elements. For one example, graphene is a crystalline allotrope of carbon in the form of a nearly transparent (to visible light) one atom thick sheet. Borophene is a crystalline atomic monolayer of boron and is also known as boron sheet. An example of two-dimensional transition metal dichalcogenide (TMD) is monolayer molybdenum disulfide (MoS₂) or molybdenum selenide (MoSe₂). MXenes are a class of two-dimensional inorganic compounds that consist of atomically thin layers of transition metal carbides, nitrides, or carbonitrides.

Nanoporous dielectric layer (NDL) with pores embedded in the dielectric layer can enable such deformability in the z direction. However, most of NDL process are focused on inorganic materials (e.g., SiCOH) and pores are generated by removing the co-deposited sacrificial organic porogens through high energy curing processes including heat, electron beam, and ultraviolet irradiations. These high energy curing processes are not compatible with organic polymer dielectric materials, calling for the development of high-resolution fabrication technologies for polymer-based NDL.

The present disclosure provides a capacitor at nanometer level, a nanodevice or device such as a sensor comprising the capacitor, methods of making the same, and methods of using the same.

In accordance with some embodiments, the nanodevice includes a substrate, and a first 2D material layer disposed over the substrate, and comprising a 2D material and being electrically conductive. The nanodevice further includes a polymeric nanoporous dielectric layer (NDL) disposed on the first 2D material layer. The polymeric NDL comprises a polymer having a crystalline structure and having lamellae substantially normal to a plane of the first 2D material. The polymeric NDL is made by using the first 2D material layer as a template in an atomic template assembly (ATA) process.

A conductive material layer is disposed on the polymeric NDL. The conductive material layer comprises a second 2D material layer or comprises a different electrically conductive material. The first 2D material, the polymeric NDL, and the conductive material layer are configured to provide a capacitor structure at a nanometer level.

In some embodiments, the polymeric NDL has pores aligned with the lamellae and normal to the first 2D material layer. The porosity may be in a range of from about 60% to about 95% by volume, for example, in a range of from about 80% to 90% by volume. The polymeric NDL may have a thickness in a range of from about 1 nm to about 5,000 nm.

For example, in some embodiments, the polymeric NDL may have a thickness in a range of from about 5 nm to about 1,000 nm, for example, in a range of from about 5 nm to about 500 nm, in a range of from about 5 nm to about 400 nm, in a range of from about 5 nm to about 300 nm, in a range of from about 5 nm to about 200 nm, in a range of from about 5 nm to about 100 nm, in a range of from about 5 nm to about 50 nm, in a range of from about 8 nm to about 500 nm, in a range of from about 8 nm to about 400 nm, in a range of from about 8 nm to about 300 nm, in a range of from about 8 nm to about 200 nm, in a range of from about 8 nm to about 100 nm, in a range of from about 8 nm to about 50 nm, in a range of from about 10 nm to about 500 nm, in a range of from about 10 nm to about 400 nm, in a range of from about 10 nm to about 300 nm, in a range of from about 10 nm to about 200 nm, in a range of from about 10 nm to about 100 nm, in a range of from about 10 nm to about 50 nm, or any other suitable thickness range.

The polymeric NDL may have a dielectric constant in a range of from 1 to 2.5, for example, from 1 to 2.

Each of the first 2D material layer and the conductive material layer may have a thickness in a range of from about 1 nm to about 5 nm. In some embodiments, each of the first 2D material layer and the conductive material layer is a monolayer. In some embodiments, the device is transparent, for example, having a transparency in a range of from about 50% to about 98%. The device has a transparency in a range of from about 80% to about 95% in some embodiments.

The polymer in the polymeric NDL is a suitable polymer having a crystalline structure. Examples of a suitable polymer include, but are not limited to, polyethylene, polypropylene, any other polyolefins, polyester, polyamide, acetal, and any combination thereof. For example, the some embodiments, the polymer in the polymeric NDL is polyethylene, which may include, but is not limited to, high density polyethylene (HDPE) or low density polyethylene (LDPE).

The 2D material in the first or the second 2D material layer can be any suitable 2D material that is electrically conductive. Examples of a suitable 2D material include, but are not limited to graphene, borophene, transition metal dichalcogenide, germanene, boron nitride nanosheet, titanate nanosheet, borocarbonitride, MXene, and any combination thereof. For example, in some embodiments, the 2D material comprises graphene. In some other embodiments, the 2D material comprises a transition metal dichalcogenide such as MoSe₂, WSe₂, MoS₂, and WS₂.

In the nanodevice, the polymeric NDL may have a dielectric constant in a range of form about 1.1 to about 1.2.

In accordance with some embodiments, the nanodevice, which has a hybrid nanostructure, is a sensor. Examples of a suitable sensor include, but are not limited to, a pressure sensor, a weight sensor, a mass sensor, a temperature sensor, a gas sensor, and any combination thereof.

The nanodevice may further comprise two conductive pads disposed on the substrate and electrically connected with the first 2D material layer and the conductive material layer. In some embodiments, the conductive material layer comprises a portion disposed on the substrate.

In another aspect, the present disclosure provides a method of making the nanodevice (or the capacitor or the sensor). Such a method comprises a step of growing the polymeric NDL on the first 2D material layer as a template.

In another aspect, the present disclosure provides a method of using the nanodevice (or the capacitor or the sensor). Such a method comprises a step of measuring a capacitance or a change in the capacitance of the capacitor.

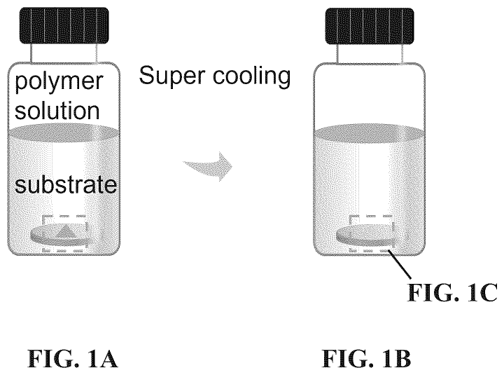

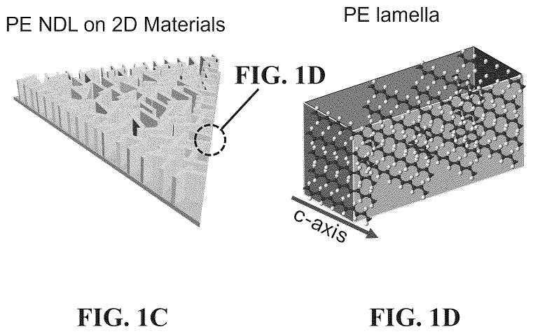

The methods are described with reference to the exemplary structures described in the figures, for example, FIGS. 1A-1D, 8A-8F, 9A, 11, and 15A-15B.

In accordance with some embodiments, organic polymers such as high-density polyethylene (PE) nanoporous dielectric layer (NDL) have been made through atomic templated assembly on monolayer two dimensional (2D) materials (e.g., MoSe₂ and graphene) supported by any suitable substrates. The height of PE layer can be controlled from several nanometers to hundreds of nanometers with subnanometer resolution. The combination of ultrathin monolayer 2D materials and nanoporous PE layer leads to mechanically robust thin film device that can suspend over millimeter holes. By sandwiching the PE-NDL with two layers of graphene, the inventors have obtained the thinnest inorganic-organic capacitor with only 7 nm in thickness in one example. The deformable nature of PE-NDL enables micro-Newton force sensing upon compression. The research described herein paves the way for scalable and high-definition fabrication of robust and sensitive soft electronics.

The high-density polyethylene (PE) can form NDL comprising interconnected PE lamellae with a width of 10-20 nm and a controllable height from several to hundreds of nanometers on monolayer two-dimensional (2D) materials such as MoSe₂ or graphene through an atomic-templated assembly (ATA) process. The samples of PE-NDLs have been made on flat and curved, microscale and inch-scale 2D materials template. The PE-NDL significantly enhances the mechanical robustness of 2D materials leading to large scale suspended devices. In the thinnest inorganic-organic capacitor made up to date as demonstrated in the present disclosure, a 5-nm-thick PE-NDL is sandwiched between two layers of graphene, and the overall thickness of the full capacitor is 7 nm. Such capacitor with the deformable PE-NDL leads to a thin-film electronic device such as an ultrasensitive pressure/weight sensor.

### Examples

### 1. Methods and Materials

### 1-1. Synthesis of MoSe₂

To synthesize MoSe₂, 700 mg selenium (Se) and 15 mg molybdenum oxide (MoO₃) powder were used as the Se and Mo precursors. A single side polished Si/SiO₂ was used as the growth substrate which was placed upon the MoO₃ powder crucible with the polished surface facing down towards the bottom of the crucible. The MoO₃ crucible was put at the center of the fused quartz tube and the Se was located at the upstream region with a temperature of 250° C. which was measured by a thermocouple. The heating rate and the growth temperature were 50° C./min and 760° C., respectively. The Ar/H₂(15% H₂) was used as the reaction gas with a flow rate of 35 SCCM. After 10 min growth, the furnace power was cut off and then opened the furnace and then cooled it down to room temperature naturally. The Ar/H₂ was kept providing during the cooling process.

### 1-2. MoSe₂-PE Hybrid Nanostructure Fabrication

The HDPE was dissolved in the xylene (0.1 mg/ml) under 130° C. for 30 min. The solution was transferred to another oil bath with fixed crystallization temperature (90° C., 95° C., 100° C.) and kept 15 min for temperature stabilization. A pre-heated as-grown MoSe₂ in another hot pure xylene with the same temperature with the crystallization temperature was then transferred to the polymer/xylene quickly for crystallization process. After a certain time (1 min˜120 min), the sample was taken out and rinsed in hot fresh xylene and then blown dry with Ar. The HDPE used has a weight-average molecular weight of 115,828 daltons. The molecular weight of the polymer such as HDPE can be any be in any suitable range, for example, from 100,000 to 1,000,000. The molecular weight can be tested by using gel permeation chromatography (GPC).

### 1-3. Fabrication of Capacitor and Capacitor Based Sensor

The fabrication and the structures of a capacitor and a resulting sensor are described in figures, for example, for example, 8A-8F, 9A, 11, and 15A-15B. In accordance with some embodiments, an exemplary capacitor or sensor comprises a first 2D material layer, a polymer based nanoporous dielectric layer (NDL), and a second 2D material layer. The polymer NDL is disposed between the first and the second 2D material layer. The polymer may have a crystalline structure. For example, in some embodiments, such a capacitor or sensor include graphene/PE NDL/graphene. In some embodiments, the first 2D material layer and the second 2D material layer are monolayers. In some embodiments, the second 2D material layer can be replaced with any conductive layer such as a metallic layer or conductive ceramic layer. The first 2D material layer provides a template for the polymer to grow and crystalize during the fabrication process.

In another aspect, the present disclosure also provides a device comprising a sensor or capacitor described herein, and the method of making and the method of using the same.

The dielectric layer (DL) in electronics is usually made from dense ceramics or polymer to provide effective gate modulation for transistors or energy storage capabilities. However, a dense ceramic or polymer layer cannot provide desirable deformability for applications such as capacitor-based touch sensors. Researchers have developed micro and macrostructures in DL that can deform upon external pressure. And the decreased distance between the two electrodes leads to the change of capacitance and creates pressure sensitivity. It is important to note that the existing methods of making these deformable DL structures face the challenge of further reducing the thickness to the nanoscale. In the present disclosure, an atomic-templated assembly (ATA) method has been demonstrated to manufacture the polymeric nanoporous dielectric layer (NDL) on two-dimensional (2D) material.

FIGS. 1A-1D illustrate the solution growth process of the polymeric nanoporous dielectric layer (NDL) on one 2D material in accordance with some embodiments.

The inventors first synthesized monolayer 2D materials, for example, MoSe₂ and graphene, on a substrate of Si/SiO₂ through chemical vapor deposition (CVD) process. As illustrated in FIGS. 1A-1B, the substrate having a 2D material, such as Si/SiO₂ substrate with a 2D material, was put into a solution of a polymer, for example, a solution of polyethylene (PE) in xylene. In some embodiments, a super cooling is applied.

As illustrated in FIGS. 1C-1D, the crystal plane of the 2D material creates atomic template for the PE polymer chains to adsorb, nucleate, and assemble into lamellae. Because of the competition of polymer chains between nearby nucleation sites, there will be depletion zones formed between neighboring polymer lamellae leading to nanoporosity. The widths of polymer lamellae are in the range of 10 nm to 20 nm and several microns to tens microns in length. The depletion zone is usually sandwiched between two parallel lamellae and could be 70 nm to 200 nm in width. Therefore, the porosity of NDL can reach up to 80 to 95% by volume.

The porosity of the NDL in the present disclosure can be tailored to be in a range of from 60% to 95% by volume.

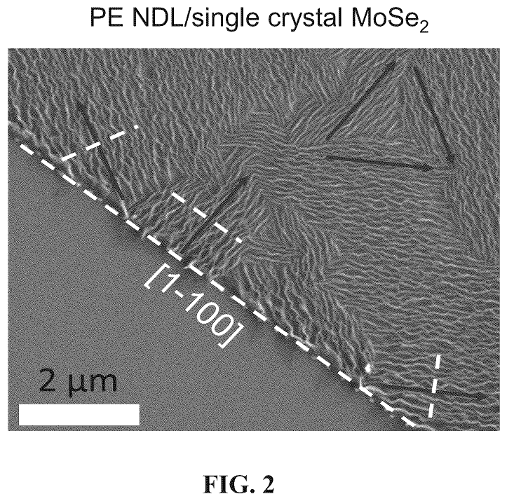

Using the atomic template assembly (ATA) method, the polyethylene (PE) nanoporous dielectric layer (NDL) was assembled on single crystalline MoSe₂ as a template. FIG. 2 shows a top-view SEM image of PE-MoSe₂ hybrid nanostructure. The polyethylene is a high-density polyethylene (HDPE).

As shown in FIG. 2, PE-MoSe₂ was used as a system for demonstration to elucidate the interaction across the polymer-template interface in the ATA assembly process. The PE molecules take an edge-on lamellar orientation on the MoSe₂ substrate, with the c-axis parallel to the substrate as shown. There are three equivalent directions for c-axis of PE to align: [1-100], [01-10], and [10-10] and PE chains fold back and forth forming lamella perpendicular to the c-axis. Although locally, small “domains” with parallel lamellae were observed macroscopically, because PE chains can take any of three orientations. No observation was made with respect to a preferred alignment of all lamellae leading to interlocks of PE lamellae.

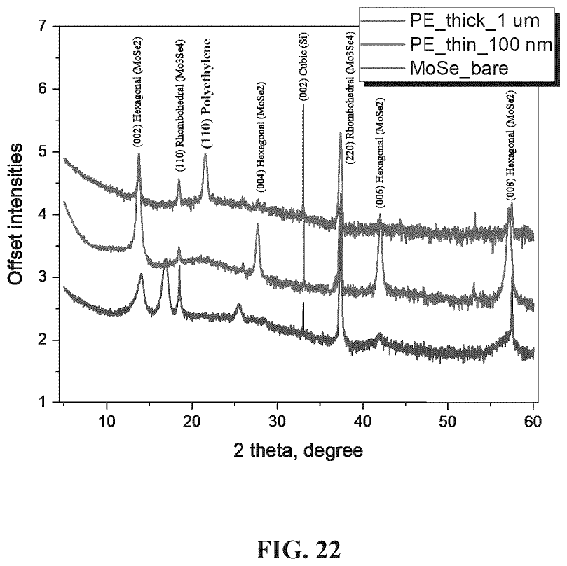

The SAED (selected area electronic diffraction) results and XRD results (FIG. 22) are consistent with the orthorhombic PE unit cell reported previously: a, b, and c are 7.4, 4.9, and 2.5 angstroms, respectively. In the planes vertical to the c axis, PE (110) planes are visible at a 2 theta value of 21.5 from grazing incidence XRD. The full-width half maxima (FWHM) of the identified (110) peak is 3.41 degrees. Because the planes (110) and (200) have a 56.3-degree angle from each other, after the (110) reflection was detected, the films were tilted 56.3 degrees, and a clearly discernable PE (200) peak was seen at a 2 theta of 24.1.

This provides evidence that the PE crystals form edge-on lamellae on the MoSe₂ surfaces. Bright field TEM images and the corresponding diffraction aperture for SAED experiments were obtained. PE (110) and (200) reflections are weak or not present in SAED, confirming the results of XRD results.

The molecular dynamics (MD) simulations show consistent results with coarse grained simulations on the interfacial epitaxial crystallography. The crystallization orientation angles, i.e. angles 0°, 60° and 120° are defined with respect to the miller-bravais direction index [12̅10] as indicated by black arrows and are measured in the counterclockwise direction. In coarse grained MD simulations, it was observed the preferential crystallization of polyethylene at 0°/[12̅10], 60°/[2̅110] and 120°/[112̅0], which are also the most preferred orientations found in all atoms MD simulations. Selenium valleys are gaps between two arrays of adjacent Selenium atoms on the MoSe₂ surface as indicated by red arrows. Selenium atoms are in top layer, molybdenum atoms are in the middle layer followed by one more selenium layer at the bottom. All three crystallization orientations of polyethylene on MoSe₂ surface <112̅0> are equivalent due to the hexagonal symmetry of MoSe₂. <112̅0> crystallization orientations are guided by carbon atoms getting trapped in Selenium valleys creating a lower potential energy material system and thus is more preferred then other crystallization orientations where carbon atoms can have continuous static hindrance with selenium atoms in the top layer. This preferential inclination of carbon atoms to crystallize in selenium valleys of MoSe₂ can be utilized to create anisotropic properties in the polyethylene MoSe₂ nanocomposite.

The growth of crystallization of polyethylene on MoSe₂ surface was also further studied. Fractional crystallization of polyethylene was evaluated at different time steps from the interface with respect to different heights in the polyethylene bulk measured perpendicular to the MoSe₂-polyethylene interface i.e. Z direction in the present study. So, Z=0 Angstroms indicates the crystallization at the MoSe₂-polyethylene interface and Z=5 Angstroms means the crystallization at a distance of 5 Angstroms from the MoSe₂-polyethylene interface in the polyethylene bulk. It can be observed that crystallization of polyethylene starts at the MoSe₂-polyethylene interface and the crystallization growth front moves towards the bulk polyethylene. Crystallization growth front moves rapidly from 0 to 6.01 Angstroms in the first 25 ns but in the next 75 ns crystallization growth front moves slowly and reaches up to 8.67 Angstroms distance from the interface. Since periodic boundary conditions were used, there are two crystallization growth fronts, which limit the maximum height of the crystalline polyethylene in MD simulations. It was found that polyethylene crystalline from the surface of 2D materials and the height of crystalline domain is proportional to the crystallization time.

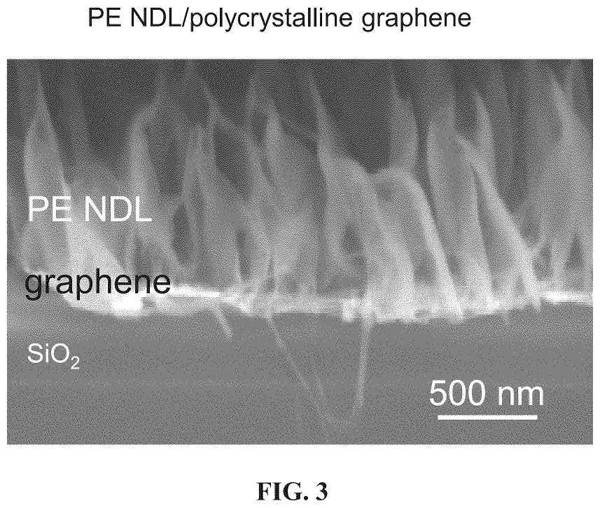

Using the ATA method, the PE nanoporous dielectric layer (NDL) was assembled on polycrystalline graphene as a template. FIG. 3 shows a side-view SEM image of PE-graphene hybrid nanostructure.

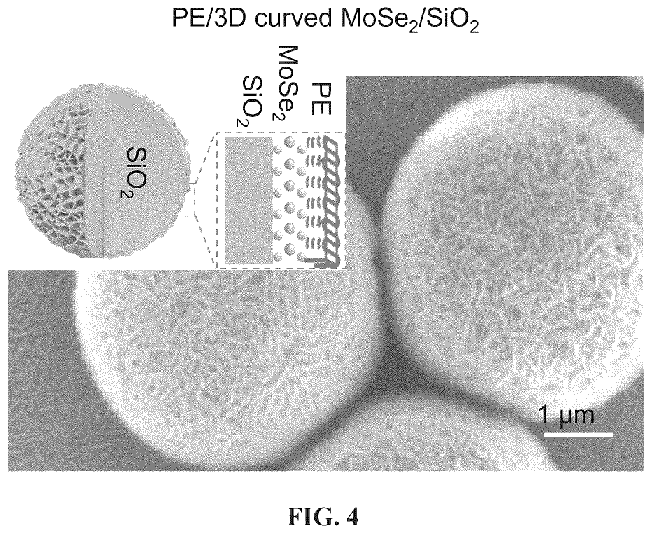

Using the ATA method, the PE nanoporous dielectric layer (NDL) was assembled on a curved MoSe₂ surface. FIG. 4 is a SEM image showing PE-MoSe₂ on SiO₂ particles, while the insert is a cross-sectional schematic illustration. The MoSe₂ was grown on the surface of SiO₂ particles. The bending of the MoSe₂ surface does not affect its capability to guide the assembly of the PE chains.

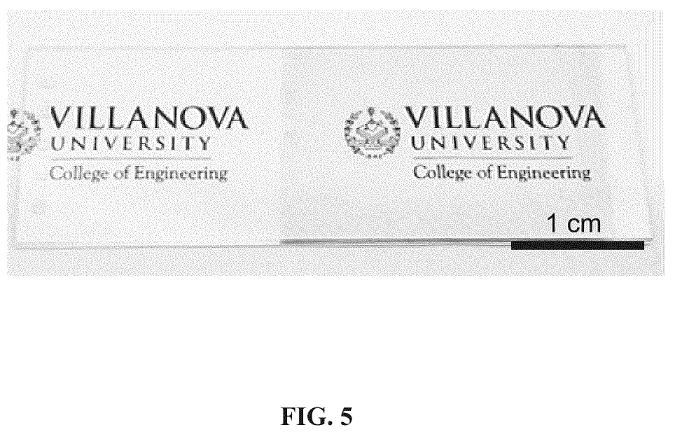

Large scale assembly of NDL have been demonstrated on inch-scale graphene film supported on a transparent glass slide. The lateral size of the NDL is only limited by the size of 2D material template. FIG. 5 shows an inch-scale PE-graphene film on glass slide. The sample showed high transparency.

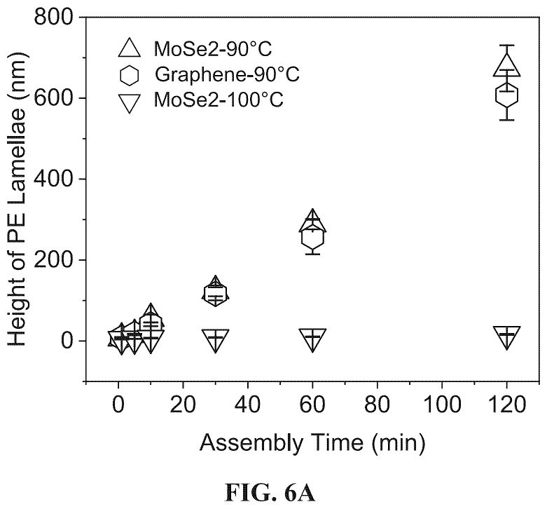

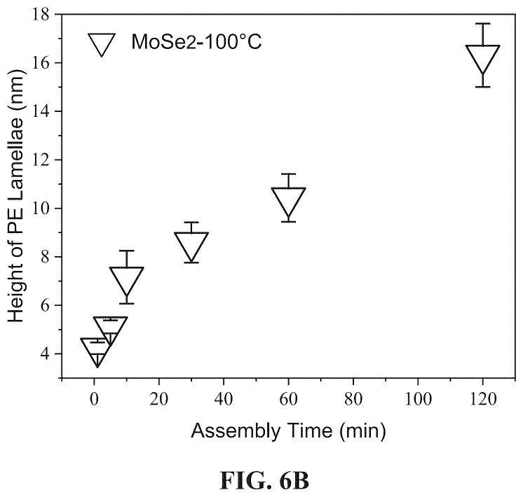

FIG. 6A shows the relationship between the height of the PE lamellae and the assembly time under different temperatures and on different substrates. FIG. 6B shows the relationship between the height of the PE lamellae and the assembly time under 100° C. and on MoSe₂ substrate.

Applying the ATA method, the height of PE lamellae on different 2D materials, for example, MoSe₂ and graphene, can grow from several nanometers to hundreds of nanometers with sub-nanometer resolution. Under different temperatures, the assembly rate is different. The PE lamellae can growth more than hundreds nanometers at 90° C. while only ten more nanometers at 100° C.

Through an atomic-templated assembly (ATA) method, the crystalline surface of 2D materials can be utilized as template to initiate epitaxy assembly of polymer chains from a diluted solution. However, effort has never been made to combine atomic thin 2D material monolayers with polymer crystals to build ultrathin soft capacitors and devices. In the present disclosure, monolayer 2D materials such as MoSe₂ and graphene obtained were synthesized through chemical vapor deposition (CVD) process. Raman spectroscopy was used to detect and characterize monolayer 2D materials.

PE was dissolved in hot xylene at 130° C. forming a diluted solution. The solution was cooled down to a crystallization temperature (e.g., 90° C. and 100° C.). A monolayer 2D material covered SiO₂/Si substrate was submerged in the solution to initiate the heterogeneous nucleation and crystal growth of PE. PE-NDL can be assembled on single crystalline MoSe₂ and polycrystalline graphene. Moreover, PE-NDL can be assembled on curved crystalline surface of MoSe₂ in which MoSe₂ was directly grown on the surface of SiO₂ beads in a CVD process. The lateral dimension of PE-NDL is only limited by the size of the atomic template and an inch-scale HDPE-NDL can be assembled on graphene transferred on a transparent glass slide. Adding nanostructured PE-NDL can significantly increase the hydrophobicity of graphene.

The assembly kinetics can be controlled by the crystallization temperature, where larger overcooling (at 90° C.) leads to faster crystal growth rate. The heights of PE on the basal plane of MoSe₂ and graphene with respect to assembly time are summarized in FIG. 6. While higher crystallization temperature (i.e., 100° C.) reduces growth rate, the controllability can be significantly enhanced to sub-nanometer scale. The height of PE lamellae on MoSe₂ grows from 4.2 nm at 1 min to 7.2 nm at 10 min (growth rate_{1-10 min}=0.3 nm/min) and then to 16.31 nm at two hours (growth rate_{10-120 min}=0.08 nm/min).

It was also found at the same crystallization temperature of 90° C., the growth rate of PE on MoSe₂ is slightly higher than that on graphene. The height of PE on the basal plane of 2D materials is a particular interest for the purpose of thin film device fabrication. With MoSe₂, higher PE lamellae can be found on Mo-terminated edge due to preferred nucleation and therefore, the heights of PE on the edge were filtered out in the thickness measurement.

These results suggest that the PE crystallized epitaxially on MoSe₂.

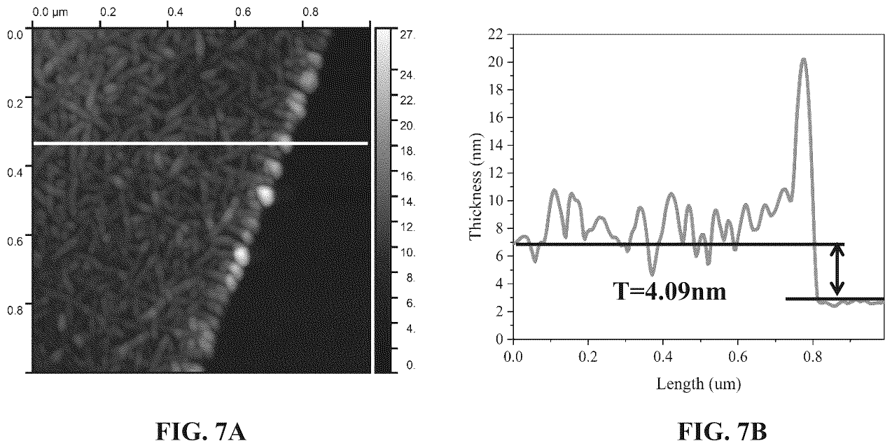

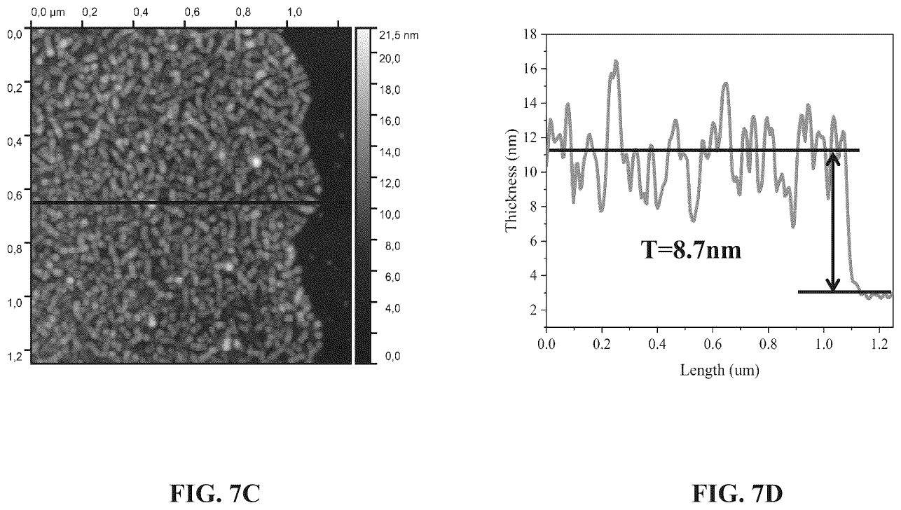

FIGS. 7A-7B and FIGS. 7C-7D show a top-view AFM image and a line profile of PE-MoSe₂ hydrid nanostructure (FIGS. 7A-7B), and PE-Graphene hybrid nanostructure (FIGS. 7C-7D), respectively. For the standard of measuring the thickness of PE NDL, the inventors chose two examples, which are MoSe₂/PE NDL and graphene/PE NDL on 1 minute assembly time at 90° C. assembly temperature condition. The line profile was obtained though atomic force microscope (AFM). For the thickness measurement, the peak values on the line profile were selected to obtain the average. However, based on our finding, monolayer MoSe₂ has the atomic edge-guided effect on PE crystallization. Therefore, the edge part of MoSe₂ has way thicker PE NDL than the basal plane, which cannot represent the true thickness of PE NDL. So the peaks from the edge part on the line profile were deleted, and the rest of peaks on basal plane were chosen to take average to get the PE NDL thickness value.

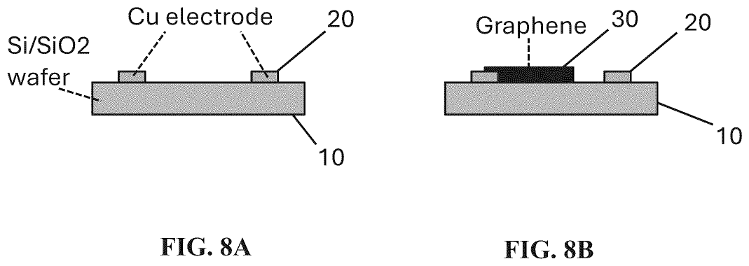

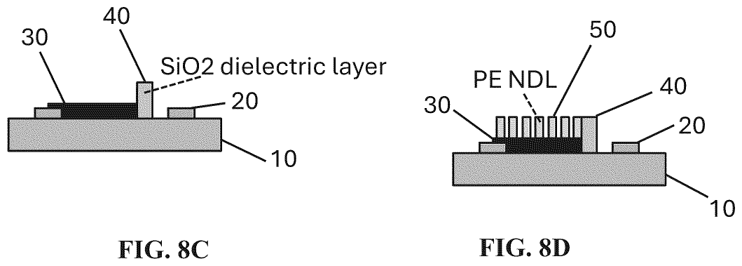

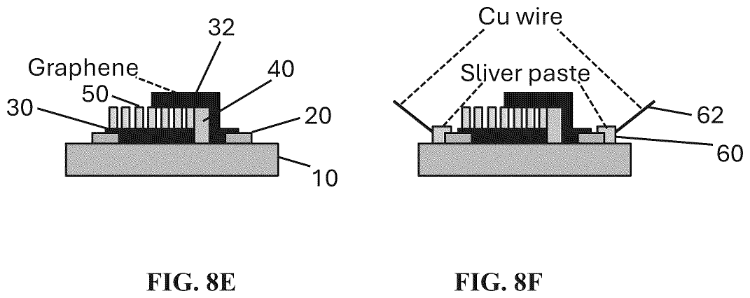

FIGS. 8A-8F are sectional views illustrating an exemplary manufacturing process of an exemplary capacitor, for example, a Graphene-Polyethylene (NDL)-Graphene (GPG) capacitor, in accordance with some embodiments.

The steps are described based on the order of the diagrams shown in FIGS. 8A-8F. The exemplary materials described in FIGS. 8A-8F are for illustration only. A thickness of a layer as described herein is a dimension in a direction (also called z-direction) perpendicular to a substrate such as a wafer comprising Si/SiO₂.

First, as illustrated in FIG. 8A, a substrate 10 is provided and at least one electrode 20 comprising a conductive material is formed onto the substrate 10. For example, copper was sputtered onto a wafer comprising Si/SiO₂ (also called the Si/SiO₂ substrate) using a sputtering machine (available from AJA International, Inc.) to provide a copper film having 50 nm in thickness. The copper film is one example of the at least one electrode 20.

At the second step, as illustrated in FIG. 8B, a first 2D material layer 30, which comprises a 2D material, is formed on the substrate 10. For example, in some embodiments, a single layer graphene (SLG) was transferred onto the Si/SiO₂ substrate with one side touched one Cu electrode though a wet transfer process. The single layer graphene (SLG) has a thickness of about 1 nm.

At the third step, as illustrated in FIG. 8C, an inorganic dielectric layer 40 is optionally formed on the substrate 10. The inorganic dielectric layer 40 may contact the 2D material layer 30 as illustrated in FIG. 8C. For example, a 40 nm-thick SiO₂ film, which is an example of the inorganic dielectric layer, was sputtered and formed over the substrate as shown in FIG. 8C, using the sputtering machine.

At the fourth step, as illustrated in FIG. 8D, the polymeric nanoporous dielectric layer 50 as described herein is formed on the 2D material layer 30. For example, the xylene/PE solution was applied to grow a 40.3 nm-thick PE NDL on the SLG layer using the ATA method. a polymeric nanoporous dielectric layer 50 as described herein may be described and labeled by its thickness.

At the fifth step, as illustrated in FIG. 8E, a conductive layer 32, which may be a second 2D material layer comprising a 2D material or any other conductive layer comprising any other electrically conductive material, is formed over the polymeric NDL 50. For example, a monolayer graphene was transferred onto the top of PE/graphene film with the other side contacted with the Cu electrode.

At the sixth step, as illustrated in FIG. 8F, further electrical connection may be connected to the electrodes 20 of the resulting capacitor structure formed. These electrical connections may include electrical wires 62 connected with the electrodes 20 through conductive paste 60. For example, as illustrated in FIG. 8F, the Cu wires were connected on each side of Cu electrode with silver paste.

In the experiments, a SiO₂ wall with the same height of PE NDL was created to prevent the device short caused by the contact of top layer graphene and bottom layer graphene.

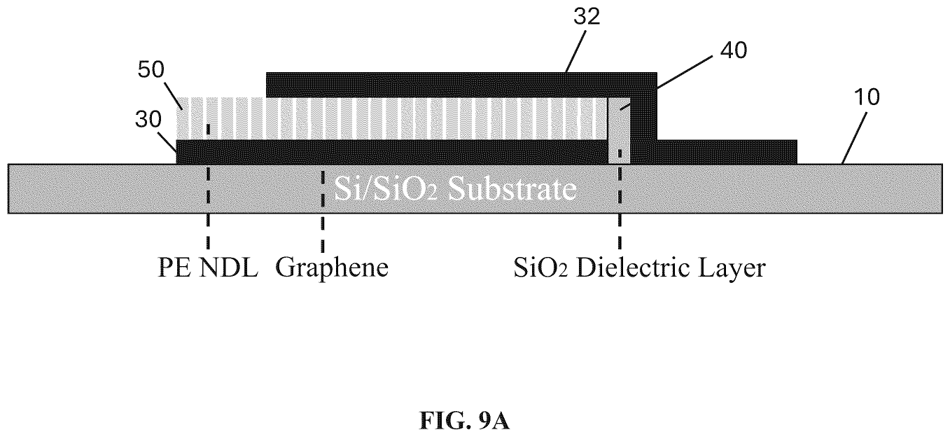

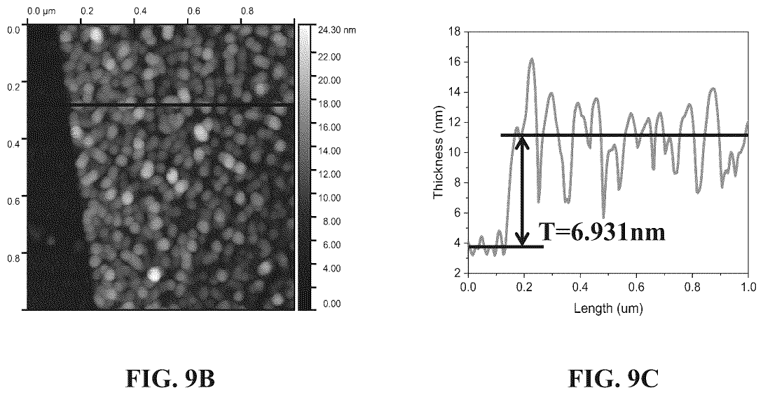

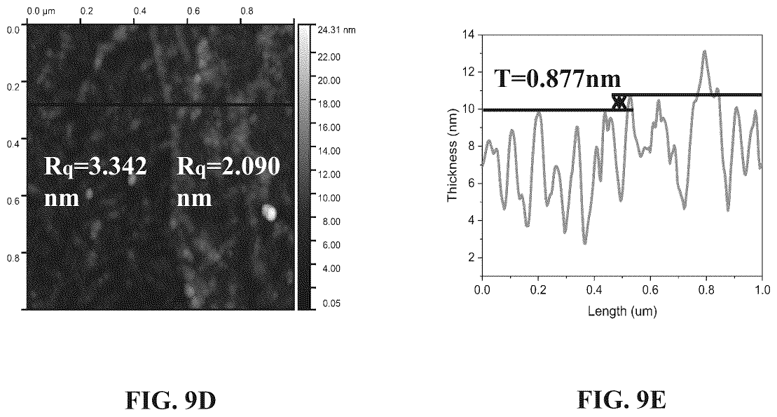

FIG. 9A is a sectional view schematically illustrating an exemplary Graphene-Polyethylene (NDL)-Graphene (GPG) capacitor in accordance with some embodiments. The exemplary GPG capacitor of FIG. 9A has a structure similar to that of the capacitor illustrated in FIGS. 8E-8F and are made using the same process as illustrated in FIGS. 8A-8F. The capacitor comprises a substrate 10, a first 2D material layer 30 disposed on the substrate 10, a polymeric nanoporous dielectric layer 50 disposed on the 2D material layer 30, and a conductive layer or a second 2D material layer 32. The capacitor may further include an inorganic dielectric layer 40 separate the first 2D material layer 30 and the conductive layer or the second 2D material layer 32. The inorganic layer 40 may contact the polymeric nanoporous dielectric layer 50.

FIGS. 9B-9C and FIGS. 9D-9E show a top-view AFM image and a line profile of Graphene-PE and Graphene-PE-Graphene, respectively.

The thickness of the PE NDL is controllable. The PE NDL with different thickness (such as 6.1 nm and 40.3 nm) were obtained due to the controllability of subnanometer resolution PE NDL assembly. The overall capacitor thickness can be as low as 7.8 nm, which is the thinnest organic-inorganic hybrid capacitor to the best knowledge of the inventors.

Limited by the scale of AFM image scan (maximum is 50 μm×50 μm), the inventors measure the overall thickness of GPG capacitor by scanning the substrate/Graphene-PE area and Graphene-PE/Graphene area. The height of Graphene-PE and Graphene (top layer) based on the line profile were calculated with the same standard on FIG. 7. The two parts of height were added together to get the overall thickness of GPG capacitor.

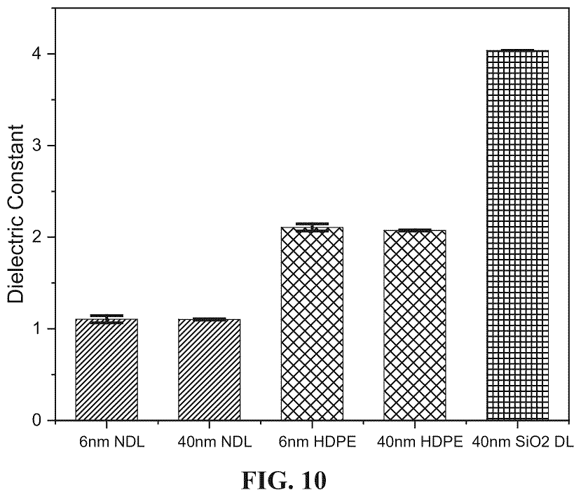

FIG. 10 shows the dielectric constant data of the capacitors comprising 6.1 nm PE NDL, 40.3 nm PE NDL, 6.1 nm HDPE lamellae, 40.3 nm HDPE lamellae, and 40.0 nm SiO₂ DL. Except the capacitor with 40 nm SiO₂ DL, the capacitors comprising polyethylene (PE) are GPG capacitors. Unless indicated otherwise, a numerical values in a label for a capacitor represents a respective thickness of each dielectric layer (DL) in the capacitor. Each capacitor included at least one 2D material layer such as a graphene layer disposed on first side of the capacitor, and another conductive layer disposed on a second side of the capacitor. The conductive layer disposed on a second side may be a 2D material layer such as a graphene layer.

An LCR meter was used to measure the capacitance. The sampling frequency was 10 points per second speed to get 600 capacitance value in 60 seconds for an average to get each capacitance value. For the dielectric constant, the following formula was used to calculate:

Dielectric constant (ε)=(Capacitance of the capacitor)/[(Permittivity of free space)×(Effective area of the capacitor)/(Distance between the capacitor plates)],

where the capacitance of the capacitor was obtained through measurement. The permittivity of free space is a physical constant, usually denoted as ε₀, with a value of approximately 8.854×10⁻¹² F/m. The effective area of the capacitor is the overlapping area between the plates. The distance between the capacitor plates is the physical distance between them.

The measured capacitance over certain area (Table. 1) for both 7.8 nm and 42.1 nm capacitors are 8.35 nF and 1.91 nF, respectively, and the dielectric constant for PE NDL is calculated to be 1.11. Table. 1 also shows the parameters for dielectric constant calculation.

TABLE 1

| | Number of | | Overlap area | Dielectric |
|---|---|---|---|---|
| | capacitors | Capacitance (nF) | (mm²) | constant |
| 6 nm PE | 1 | 7.99 | 4.74 | 1.14 |
| NDL | 2 | 7.46 | 4.75 | 1.06 |
| | 3 | 9.60 | 5.88 | 1.11 |
| 40 nm PE | 1 | 1.94 | 7.98 | 1.10 |
| NDL | 2 | 1.90 | 7.76 | 1.11 |
| | 3 | 1.91 | 7.82 | 1.11 |
| | 4 | 1.93 | 7.91 | 1.10 |
| | 5 | 1.88 | 7.79 | 1.09 |
| 40 nm | 1 | 5.09 | 5.70 | 4.04 |
| SiO₂ DL | 2 | 4.92 | 5.50 | 4.04 |
| | 3 | 5.71 | 6.40 | 4.03 |

To emphasis the sensing capability of PE NDL, SiO₂ instead of PE was used as the dielectric layer (DL), which was 40 nm in thickness, to fabricate the Graphene-SiO₂-Graphene structure capacitor. The same test standard was used as for the 42.07 nm GPG capacitor, which has a stable capacitance value of 5.24 nF, and the dielectric constant is close to the reference value (3.9) of SiO₂.

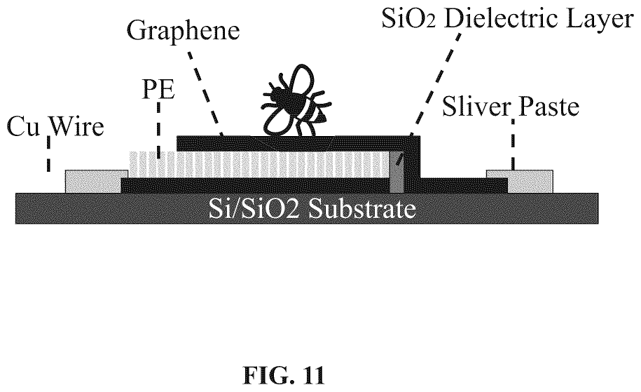

FIG. 11 a sectional view illustrating an exemplary pressure (or mass or weight) sensor made in the present disclosure.

A first graphene layer is disposed over a substrate comprising Si/SiO₂. The first graphene layer is an example of a 2D material used as a template for the growth of polymer crystalline structure. A polyethylene nanoporous dielectric layer (PE NDL) is disposed on the first graphene layer. A second graphene layer is disposed on the PE NDL. The second graphene layer also have a portion disposed on the substrate. A silicon dioxide dielectric layer is disposed in a direction normal to the substrate to separate such a portion of the second graphene layer disposed on the substrate from the first graphene layer and the PE NDL. The graphene layers are connected with two conductive pads disposed on the substrate, and the conductive pads are connected with conductive wires such as copper wires. The conductive pads are made from a silver paste. The exemplary sensor is based on an exemplary capacitor structure formed by the first graphene layer, the PE NDL, and the second graphene layer.

By using such an exemplary sensor, some measurements were made. One or more bugs were used as the weight to provide pressure onto the exemplary sensor at a nanometer scale.

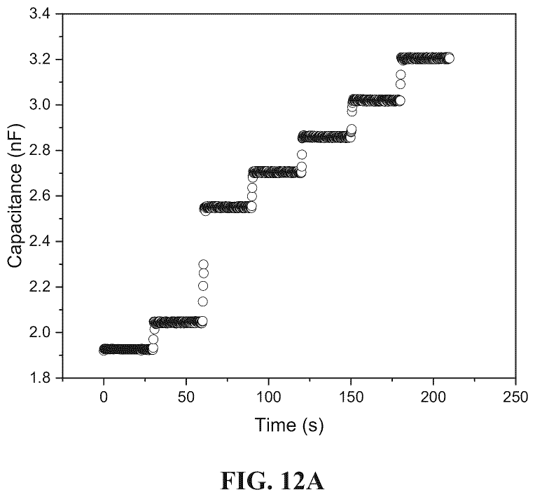

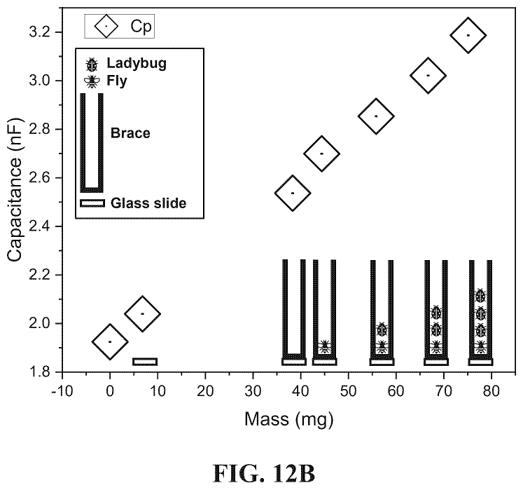

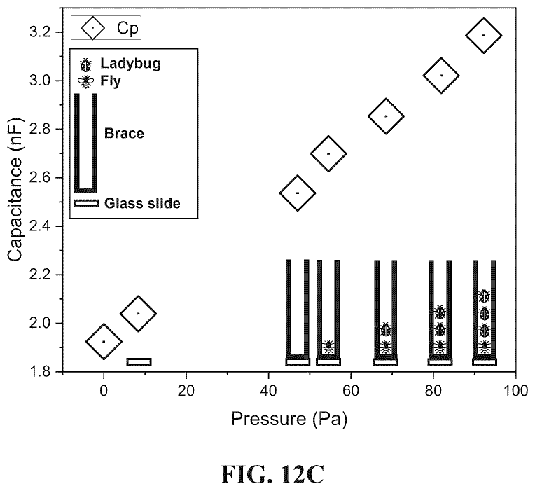

FIG. 12A shows the relationship between the capacitance and the time of a bug weight sensing test on a 42.1 nm capacitor. FIG. 12B shows the relationship between the capacitance (Cp) and the mass of a bug weight sensing test on the 42.1 nm capacitor. FIG. 12C shows the relationship between the capacitance and the pressure of the bug weight sensing test on the 42.1 nm capacitor. All the bugs used in the present disclosure were dead and dried.

The deformable PE NDL leads to capability to detect pressure. It has been demonstrated the capability to measure the weight of a dry fly. The dried fly has an average weight of 10 mg. The 42.07 nm capacitor was for this test, and it showed more stable capacitance value and dielectric constant than the 7.8 nm capacitor. An 8 mm² thin glass slide, which is only 6.8 mg, was placed on the top to protect the top single layer graphene. The different weights are added, including the brace, a first fly, a first ladybug, a second ladybug, and a third ladybug one by one and hold for one minute each. The capacitance value increased like stairs and can boost to 3.25 nF when having the overall load of one glass slide, one brace, one fly and three ladybugs. The noise level is 0.01 nF based on each loading test and capacitance increase following a linear trend versus mass (mg).

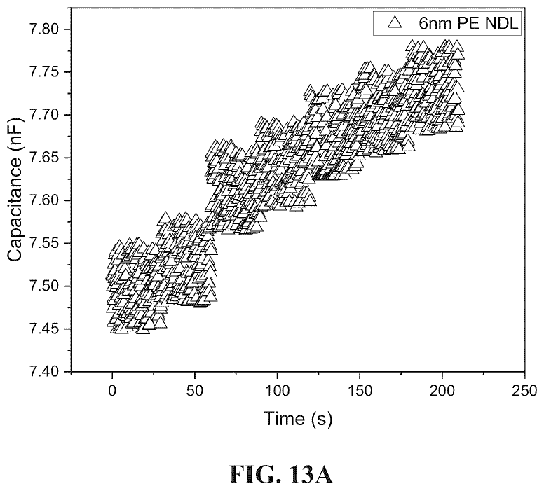

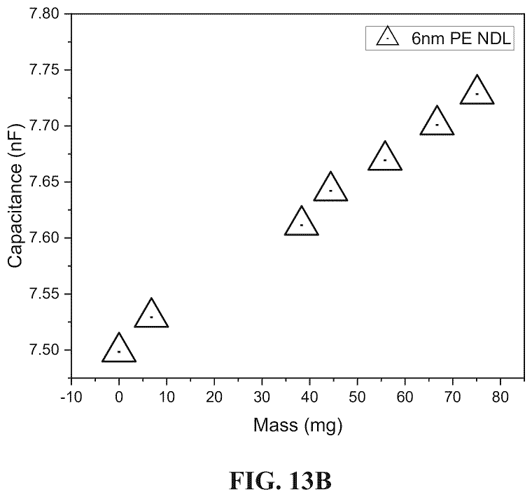

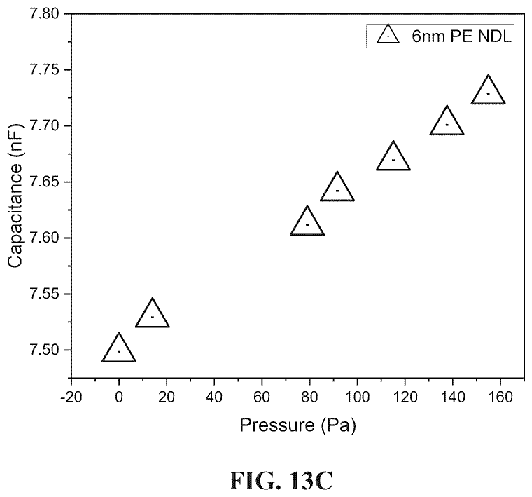

The tests based on the weight of different bugs were repeated on 7.8 nm GPG capacitor. FIG. 13A shows the relationship between the capacitance and the time of a bug weight sensing test on a 7.8 nm capacitor. FIG. 13B shows the relationship between the capacitance and the mass of bug weight sensing test on the 7.8 nm capacitor. FIG. 13C shows the relationship between the capacitance and the pressure of bug weight sensing test on the 7.8 nm capacitor. The noise level is 0.1 nF based on each loading test and capacitance increase following a linear trend versus mass (mg).

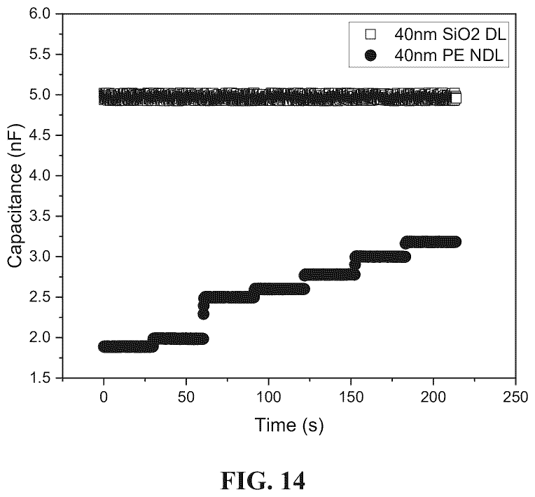

FIG. 14 shows the capacitance and the time of the bug weight sensing test on capacitors with 40 nm PE NDL and 40 nm SiO₂ DL. The sensitivity of GPG sensor can be attributed to the deformation of NDL between graphene layers. If dielectric layer is not easily deformable, the sensitivity will be poor. With the same dielectric layer thickness as GPG capacitor, the Graphene-SiO₂-Graphene structure capacitor has no sensing respond during the weight test using bugs.

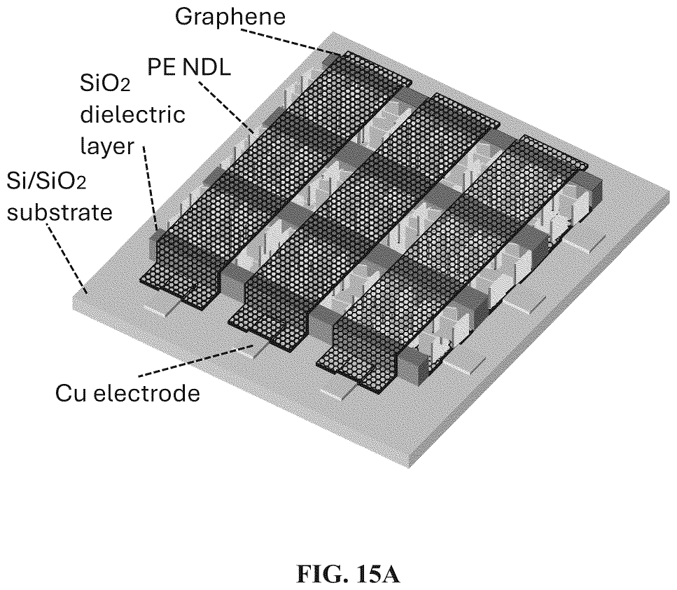

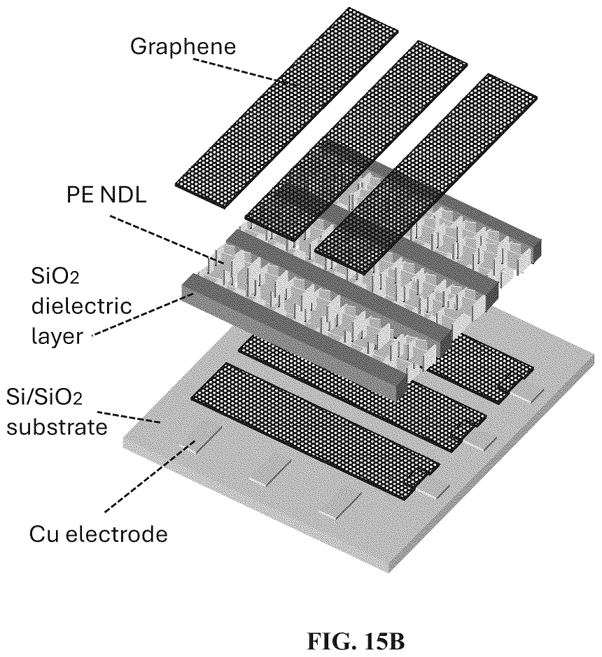

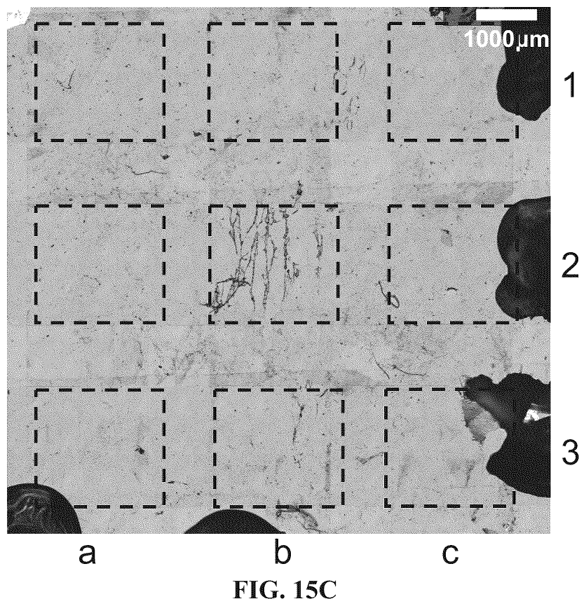

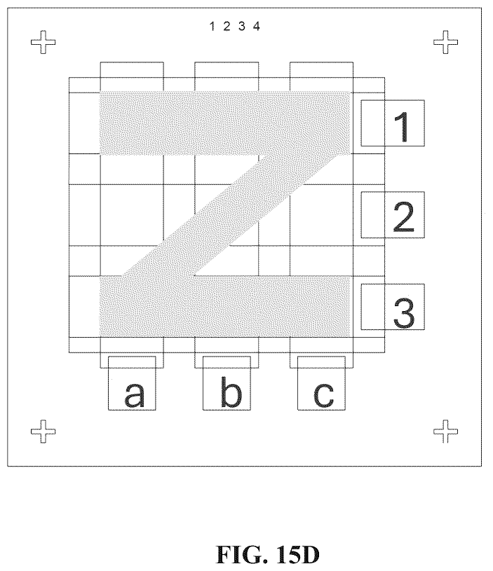

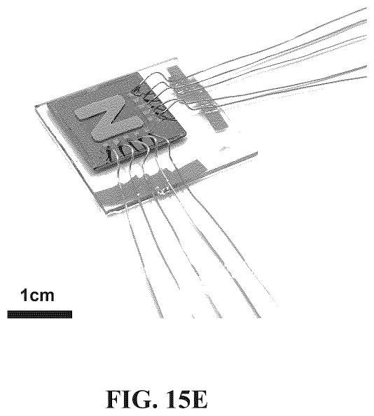

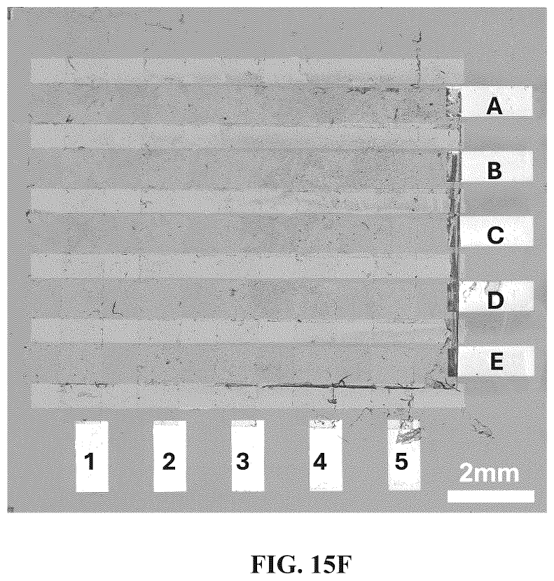

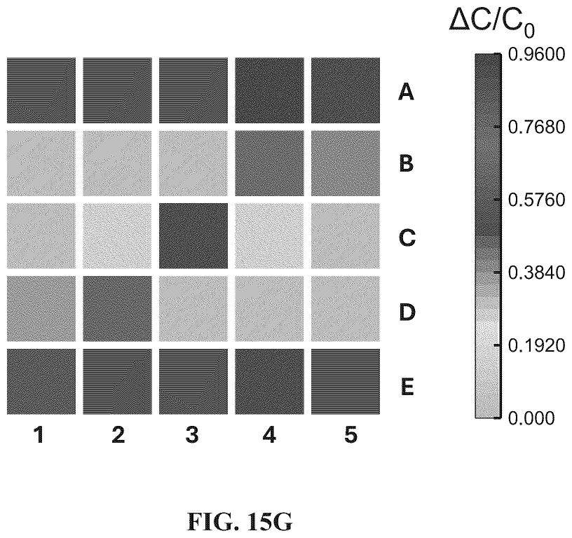

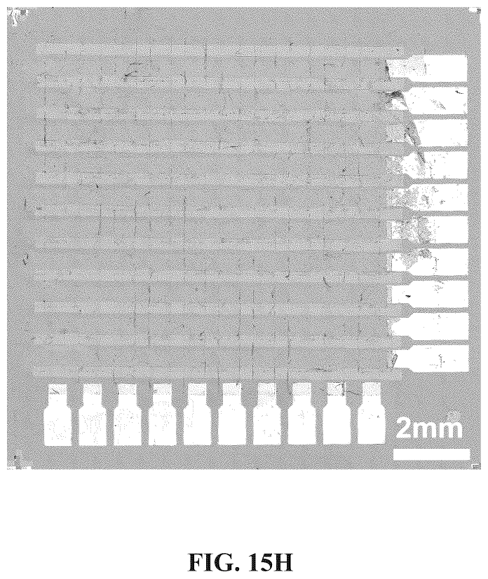

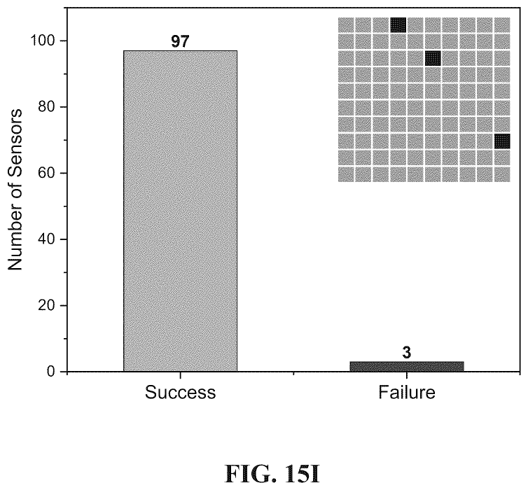

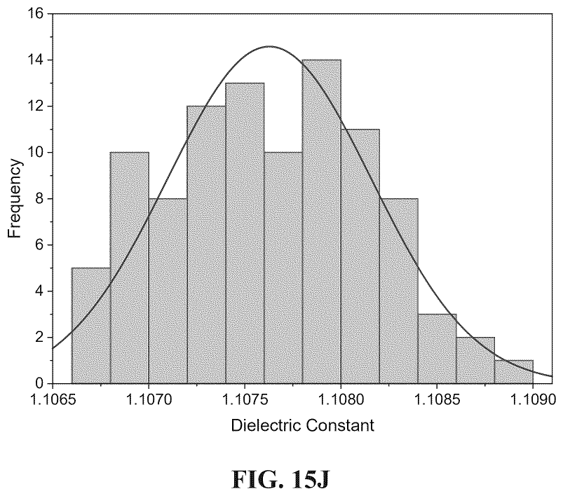

FIG. 15A is a schematic drawing illustrating an exemplary GPG capacitor having three-by-three arrays in accordance with some embodiments. A perspective view of such an exemplary GPG capacitor based sensor is illustrated. FIG. 15B is an exploded view illustrating the exemplary GPG capacitor of FIG. 15A.

Such exemplary sensor comprises a plurality of arrays, such as 3×3 arrays as shown. Each array has the structure as described in FIG. 11. The 3×3 arrays may be separate capacitors, not electrically connected with each other.

To demonstrate capabilities of pressure mapping and multi-point detection, devices having a plurality of GPG capacitors as described herein were fabricated. The plurality of GPG capacitors were in an array, for example, a 3 by 3 (3×3) array, a 5 by 5 (5×5) array, and a 10 by 10 (10×10) array. In each array, a basic unit (pixel) comprises a GPG capacitor. The 3D printed letter “Z” with the weight of 12.6 mg was put on the surface of a GPG capacitor array for the sensing test. The change in capacitance divided by the original capacitance value was used as the sensing response standard to plot a color map.

FIG. 15C is an image showing the GPG capacitor having the three-by-three arrays as shown in FIGS. 15A-15B.

Each of the total nine squares has an area in a range of from 3.436 mm² to 4.074 mm², and the corresponding capacitance value for each is in a range of from 821.07 pF to 973.95 pF. The 3D printed letter “Z” with the weight of 12.6 mg was put in the surface of the arrays GPG capacitor for the sensing test.

FIG. 15D is a schematic diagram illustrating a “Z” letter test. FIG. 15E is a perspective view illustrating the exemplary GPG capacitor under the “Z” letter test. The exemplary GPG capacitor are electrically connected with power source(s) and a testing device (not shown).

FIG. 15F illustrates five-by-five arrays in an exemplary GPG capacitor. FIG. 15G shows a color map of the five-by-five arrays in the GPG capacitor under sensing test. In the 5×5 array, the rows are labelled with A, B, C, D, and E, and the columns are labeled with 1, 2, 3, 4, and 5, respectively. Therefore, the capacitors can be located and numbered as from A1 to E5. As shown in FIG. 15G, the dark parts of the color map are exactly the letter “Z” covered area. The capacitor array can be used to test the exist of weight and shape with high sensitivity.

FIG. 15H illustrates ten-by-ten arrays in an exemplary GPG capacitor. FIG. 15I shows the success rate of the ten-by-ten arrays in the GPG capacitor under sensing test. FIG. 15J shows normal distribution of the dielectric constant values in the ten-by-ten arrays in the GPG capacitor. As shown in FIG. 15I, the success rate for detecting a weight was as high as 97% among 100 capacitors in the 10×10 array. It is expected that a device can be optimized to reach 100% detection rate. The results in FIG. 15J with a low standard deviation demonstrate the high accuracy and repeatability of the testing.

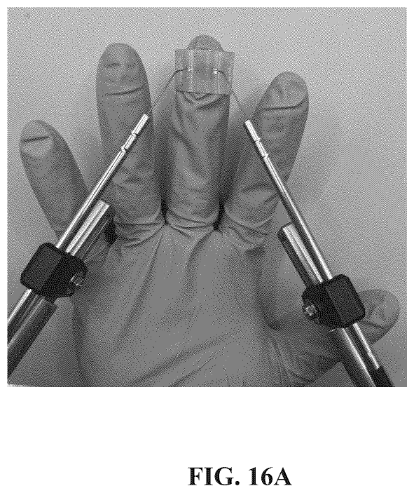

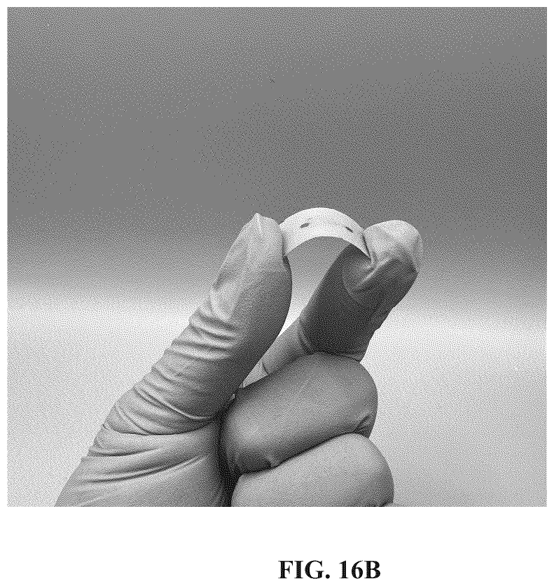

The GPG capacitor can also be fabricated on soft substrate, such as polyethyleneimine (PEI) film. FIG. 16A is an image demonstrating a GPG capacitor on a PEI substrate. FIG. 16B is an image demonstrating a side view of the GPG capacitor on the PEI substrate. This capacitor can be curved to fit human fingers.

Similar tests using a GPG capacitor on a flat PEI substrate were also performed. Such a capacitor or sensor showed good sensing response during the bug weight test.

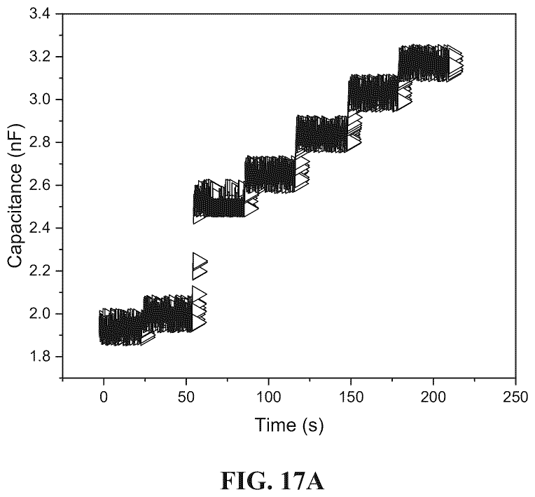

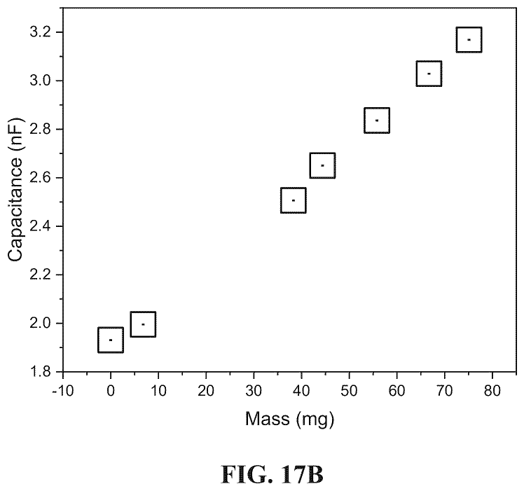

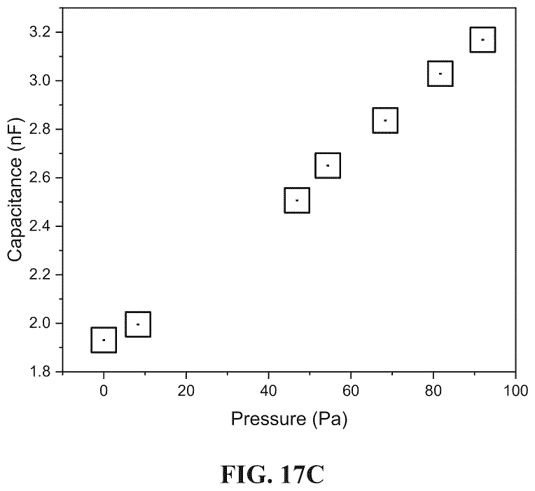

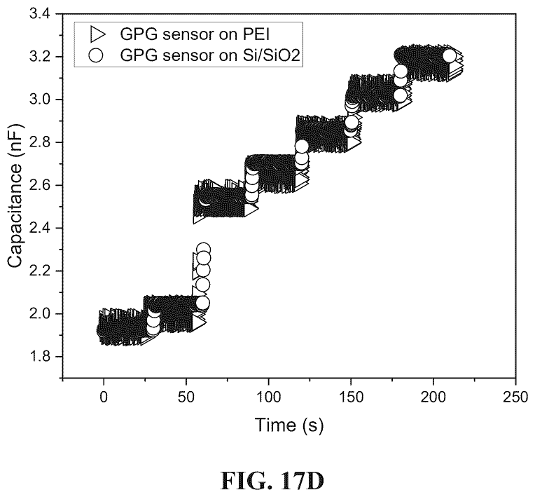

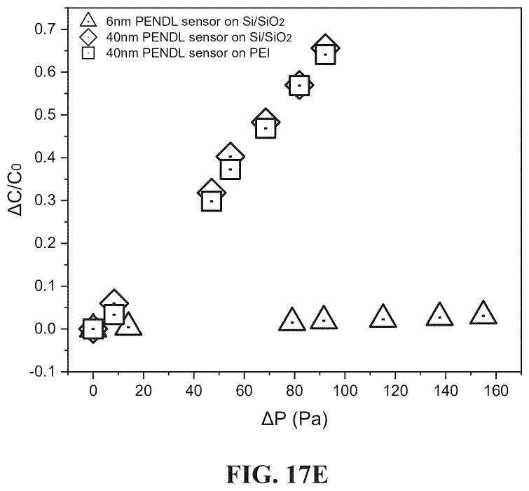

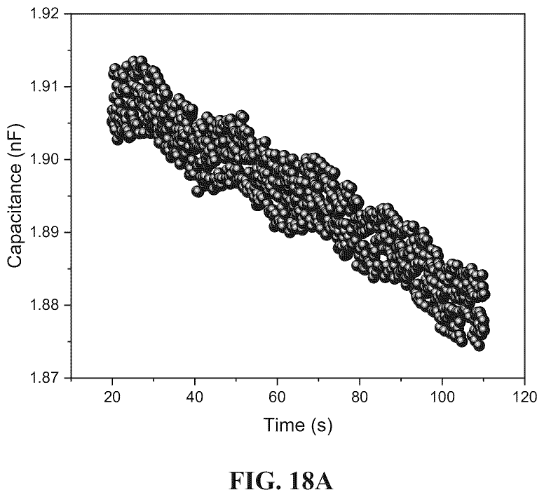

FIG. 17A shows the relationship between the capacitance and the time of bug weight sensing test on the capacitor with the PEI substrate. FIG. 17B shows the relationship between the capacitance and the mass of bug weight sensing test on the capacitor with PEI substrate. FIG. 17C shows the relationship between the capacitance and the pressure of bug weight sensing test on the capacitor with the PEI substrate. Linear relationship is shown in FIGS. 17B and 17C.

With the GPG capacitor on the PEI substrate, the noise level during the testing was higher compared to the GPG capacitor on the Si/SiO₂ substrate.

FIG. 17D compares the data of capacitance versus time of the GPG capacitors on different substrates, including Si/SiO₂ and PEI, respectively. Different pressure levels were applied at different time intervals. FIG. 17E compares the data of capacitance change versus pressure of the GPG capacitors on different substrates, including Si/SiO₂ and PEI, respectively. As shown in FIG. 17E, the sensors including PE NDL showed identical results when different substrates of the same thickness (e.g., 40 nm) were used. Compared to 40 nm PE NDL on Si/SiO₂ and 6 nm PE NDL on Si/SiO₂, the thickness of the PE NDL may be a factor in affecting the relationship between the capacitance change versus pressure. It is noted that the results of the sensor having 6 nm PE NDL on Si/SiO₂ appear to be low in the plot scale of FIG. 17E, but the data are not zero and show a linear increasing trend. The original results of the sensor having 6 nm PE NDL on Si/SiO₂ are also shown in FIG. 13B.

The capacitor or sensor in the present disclosure can be used as a weight sensor or a pressure sensor. In addition, the capacitor or sensor can be used as a temperature sensor. When the temperature change, the polymer based NDL changes it dimension, especially in the thickness in the direction normal to the substrate. Therefore, the capacitance changes with the temperature, and the temperature can be accurately measured using such a capacitor, a sensor comprising the capacitor, or a device comprising the capacitor.

For example, the PE based capacitors provided in the present disclosure were tested. The PE has the property of expansion when heated, and causes the height of NDL increase, which lead to the capacitance change of GPG capacitor. The 42.07 nm GPG capacitor was placed on a hot plate. The temperature was set to 80° C., which is a safe temperature for nanoporous PE structure since the melting point of HDPE is around 130° C.

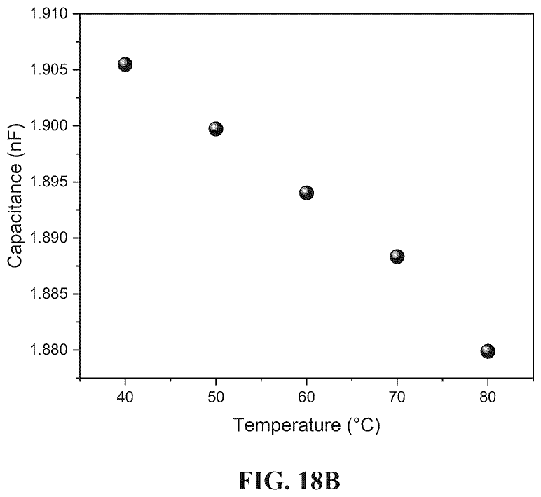

FIG. 18A shows the relationship between the capacitance and the time of a temperature sensing test. FIG. 18B shows the relationship between the capacitance and the temperature of the temperature sensing test.

With the temperature increased to 80° C., the capacitance decreased to 1.88 nF. There was a linear trend from 40° C. to 80° C.

Due to the high sensitivity of the GPG capacitor, the evaporation process of droplet can be monitored using such a capacitor. A solvent such as isopropyl alcohol (IPA) and acetone was selected as a liquid for droplet, and total three droplets for each kind of liquid was applied to the capacitor. First, an 8 mm² thin glass slide was placed on the top of the capacitor to protect the top single layer graphene. The capacitance was tested without any liquid droplet for 10 seconds. After the first droplet of the liquid was quickly dropped onto the glass slide and completely evaporated, the second droplet was applied. After the second droplet was evaporated, the last droplet was applied.

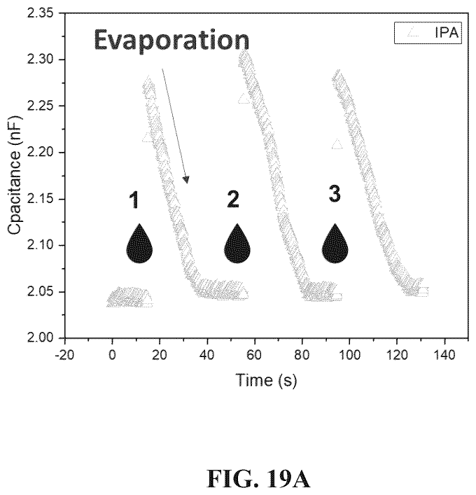

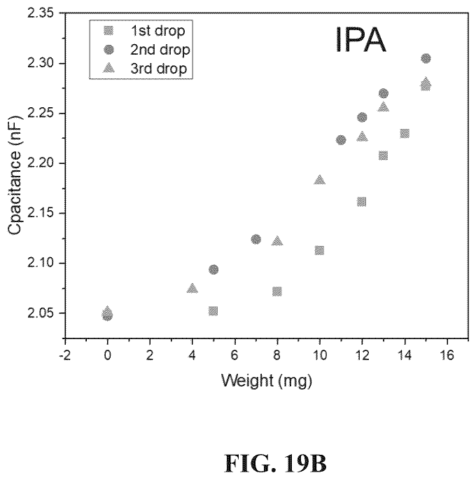

FIG. 19A shows the relationship between the capacitance and the time of IPA a liquid drop evaporation test. FIG. 19B shows the relationship between the capacitance and the weight in the IPA liquid drop evaporation test. As shown in FIGS. 19A-19B, the sensors provided in the present disclosure can be used to measure the differences in trace amount of solvent such as IPA.

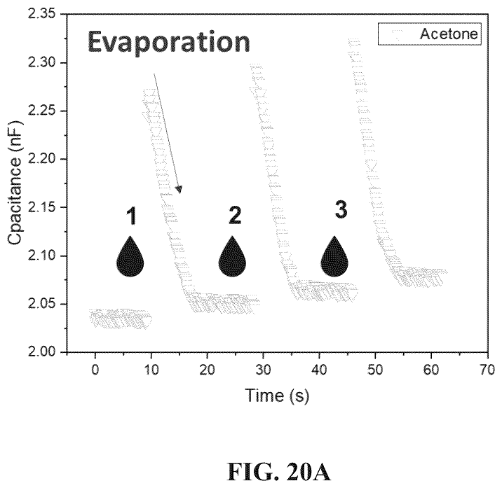

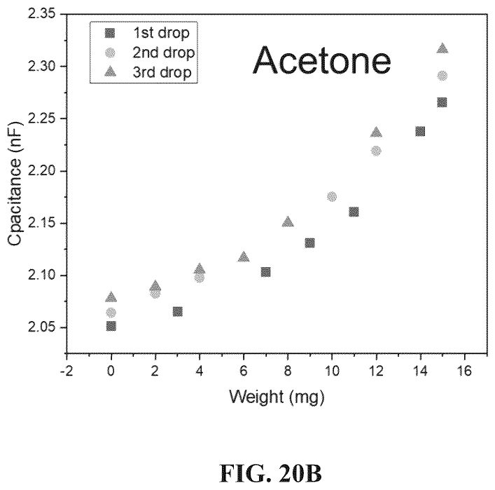

FIG. 20A shows the relationship between the capacitance and the time of the acetone liquid drop evaporation test. FIG. 20B shows the relationship between the capacitance and the weight of the acetone liquid drop evaporation test.

As shown in FIGS. 19A-19B and 20A-20B, the capacitor provides excellent sensitivity to the weight change in time. The capacitance at level of nF and the weight at level of mg or ng can be measured in seconds. The relationship between the weight and the capacitance can be also correlated.

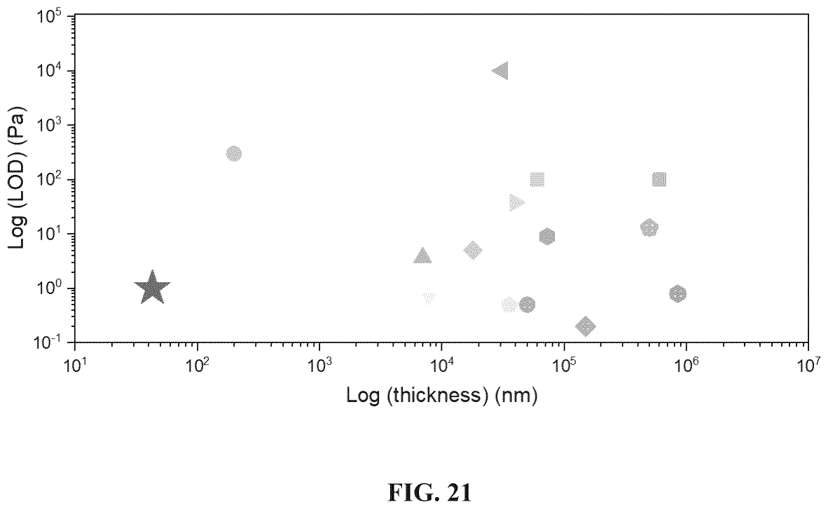

FIG. 21 compares the exemplary capacitors provided herein with comparative organic-inorganic hybrid structure-based capacitors, where have been reported in the past decade. The data points other than the star represent the performance of other capacitors previously reported.

In comparing the exemplary capacitor (indicated with a star in FIG. 21) with other reported organic-inorganic hybrid structure-based capacitors, the exemplary GPG capacitor has the thinnest overall thickness with high sensitivity. The capacitors provided in the present disclosure can be fabricated to be ultra-thin high sensitivity sensors with any substrates for force (pressure), temperature, and even gas detection.

As described above, FIG. 22 shows x-ray diffraction (XRD) of PE-MoSe₂ hybrid nanostructure.

It is worthwhile to note that the PE NDL does not only provide mechanical support, but also acts as a dielectric layer for building ultrathin capacitor with controlled thickness. For example, a monolayer graphene was transferred onto the top of a PE/graphene film and form a graphene/PE/graphene capacitor. Because the thickness of PE NDL can be controlled with subnanometer resolution, the inventors have achieved 6 nm thick PE NDL and the overall capacitor thickness is 7.8 nm, which is the thinnest organic-inorganic hybrid capacitor to our best knowledge. Each 2D material layer disposed below and above the PE NDL is about 1 nm in thickness. The deformable PE NDL leads to capability to detect pressure where the inventors have demonstrated the capability to measure the weight of fly. The dried fly has an average weight of 10 mg.

The inventors have demonstrated that the hybrid nanostructures comprising monolayer 2D materials and polymer nanocrystals can be created through a solution crystallization process. Here the monolayer 2D material is used as the ultrathin inorganic nanomaterials template for polymer nanocrystals attaching. The molecules ordering and alignment can be varied with different polymers and the polymer nanocrystals can be controlled by controlling the crystallization time and temperature. The hybrid nanostructures can show excellent mechanical performance and enhanced performance. Besides improving the fundamental understanding of the intriguing physics and fascinating functions of the nanomaterials-polymer hybrid system, the future work may explore their use in a multitude of areas, which range from ultrathin electronic and optoelectronic devices, including field-effect transistors, light-emitting diodes, and photovoltaics. To that end, the possibility of changing polymer species and 2D materials with different atomic motifs will make versatile enable applications that are not feasible with conventional materials.

The capacitor and device described herein can be used as sensors. Examples of a suitable sensor include, but are not limited to, a pressure sensor, a weight sensor, a mass sensor, a temperature sensor, a gas sensor, and any combination thereof. As described herein, the sensors show high sensitivity and accuracy.

Although the subject matter has been described in terms of exemplary embodiments, it is not limited thereto. Rather, the appended claims should be construed broadly, to include other variants and embodiments, which may be made by those skilled in the art.

What is claimed is:

1. A nanodevice, comprising:
a substrate;
a first 2D material layer disposed over the substrate, and comprising a 2D material and being electrically conductive;
a polymeric nanoporous dielectric layer (NDL) disposed on the first 2D material layer, wherein the polymeric NDL comprises a polymer having a crystalline structure and having lamellae substantially normal to a plane of the first 2D material; and
a conductive material layer disposed on the polymeric NDL, wherein the conductive material layer comprises a second 2D material layer or comprises a different electrically conductive material,
wherein the first 2D material, the polymeric NDL and the conductive material layer are configured to provide a capacitor structure at a nanometer level.

2. The nanodevice of claim 1, wherein the polymeric NDL has pores aligned with the lamellae and normal to the first 2D material layer, and the porosity is in a range of from about 60% to about 95% by volume.

3. The nanodevice of claim 2, wherein the porosity is in a range of from about 80% to 90% by volume.

4. The nanodevice of claim 1, wherein the polymeric NDL has a thickness in a range of from about 1 nm to about 5,000 nm.

5. The nanodevice of claim 1, wherein each of the first 2D material layer and the conductive material layer has a thickness in a range of from about 1 nm to about 5 nm.

6. The nanodevice of claim 1, wherein each of the first 2D material layer and the conductive material layer is a monolayer.

7. The nanodevice of claim 1, wherein the nanodevice has a transparency in a range of from about 50% to about 98%.

8. The nanodevice of claim 1, wherein the nanodevice has a transparency in a range of from about 80% to about 95%.

9. The nanodevice of claim 1, wherein the polymeric NDL is made by using the first 2D material layer as a template in an atomic template assembly (ATA) process.

10. The nanodevice of claim 1, wherein the polymer in the polymeric NDL is selected from the group consisting of polyethylene, polypropylene, any other polyolefins, polyester, polyamide, acetal, and any combination thereof.

11. The nanodevice of claim 1, wherein the polymer in the polymeric NDL is polyethylene.

12. The nanodevice of claim 1, wherein the 2D material is selected from graphene, graphene oxide, borophene, transition metal dichalcogenide, germanene, boron nitride nanosheet, titanate nanosheet, borocarbonitride, MXene, or any combination thereof.

13. The nanodevice of claim 1, wherein the 2D material comprises graphene.

14. The nanodevice of claim 1, wherein the 2D material comprises transition metal dichalcogenide.

15. The nanodevice of claim 14, wherein the transition metal dichalcogenide comprises MoSe₂.

16. The nanodevice of claim 1, wherein the polymeric NDL has a dielectric constant in a range of form about 1.1 to about 1.2.

17. The nanodevice of claim 1, wherein the nanodevice is a sensor.

18. The nanodevice of claim 17, wherein the sensor is a pressure sensor, a weight sensor, a mass sensor, a temperature sensor, or a gas sensor.

19. The nanodevice of claim 17, further comprising conductive pads disposed on the substrate and electrically connected with the first 2D material layer and the conductive material layer.

20. The nanodevice of claim 1, wherein the conductive material layer comprises a portion disposed on the substrate.

21. A method of making the nanodevice of claim 1, comprising a step of growing the polymeric NDL on the first 2D material layer as a template.

22. A method of using the nanodevice of claim 1, comprising a step of measuring a capacitance or a change in the capacitance of the capacitor.
